(19) United States
(12) Patent Application Publication
(10) Pub. No.: US 2012/0298414 A1
(43) Pub. Date: Nov. 29, 2012

(54) SHIELD FOR SHIELDING ELECTROMAGNETIC WAVES

(75) Inventor: Hyun Sook PARK, Changwon-si (KR)

(73) Assignee: SUNG DUK ELECTRONICS CO., LTD., Changwon-si (KR)

(21) Appl. No.: 13/245,058

(22) Filed: Sep. 26, 2011

(30) Foreign Application Priority Data
May 26, 2011 (KR) 10-2011-0050023

(51) Int. Cl. H05K 9/00

(52) U.S. Cl. 174/382

(57) ABSTRACT

Provided is a shield for shielding electromagnetic waves, which can easily perform maintenance and repair of circuit elements without separating the shield from a circuit board even after the shield is fixed on the circuit board. In a shield for shielding electromagnetic waves formed in the shape of a box having an opened bottom so as to cover circuit elements disposed on a circuit board, the shield is composed of a shield cover corresponding to a top surface thereof and a shield wall corresponding to a sidewall thereof, and the shield cover includes a frame and a cut-away part cut away at an inside of the frame. The cut-away part opens/closes the inside of the frame of the shield cover as the other side of the cut-away part is rotated using one side of the cut-away part as a rotational axis.

### CROSS-REFERENCES TO RELATED APPLICATIONS

The present application claims priority under 35 U.S.C 119(a) to Korean Application No. 10-2011-0050023, filed on May 26, 2011, in the Korean Intellectual Property Office, which is incorporated herein by reference in its entirety set forth in full.

### BACKGROUND OF THE INVENTION

Exemplary embodiments of the present invention relate to a shield for shielding electromagnetic waves, which covers electronic components mounted on printed circuit boards (PCBs) of various types of electronic devices so as to shield electromagnetic interference (EMI).

Recently, with the rapid development of electronic and communication technologies, it has been technically possible to use unit circuits having various functions, which are integrated in a limited space. However, an EMI problem occurs between adjacent circuits. In the EMI problem, a malfunction of a device is caused by the mutual interference of electromagnetic waves generated from each of the circuits.

In addition to the EMI problem, it has been continuously reported that electromagnetic waves generated from electronic devices increases the temperature of biological tissue cells due to the effect of heat, and therefore, have a bad influence on human bodies, such as weakening of immune functions or modification of genes. Accordingly, the necessity of electromagnetic wave shielding is more emphasized these days so that the electromagnetic waves do not have influence on human bodies.

The electromagnetic wave shielding generally means that in order to protect a human body or device easily Influenced by electromagnetic waves, an object to be protected is shield from an external electromagnetic wave generating source using a shield material, thereby preventing the electromagnetic waves from being transmitted to the object. The degree in which electromagnetic waves incident from the outside are attenuated by being reflected, absorbed or internally reflected by the shield material is referred to as a shielding effect.

Several methods are generally used as conventional methods for shielding electromagnetic waves. These methods are a method of shielding a circuit generating electromagnetic waves using a conductive can (shield can), a method of coating conductive silicon along joints and connections of a circuit partitioning member formed in the inside of an electronic device so as to prevent electromagnetic waves from being leaked through the joints and connections, a method of shielding a circuit for each circuit partition using a conductive shield tape formed to have the same shape as partition lines in the inside of the circuit, and the like.

The method most frequently and widely used among these methods is a method using a conductive shield. In the method, as illustrated in FIG. 1, a metal plate or thin shield 10 manufactured in the shape of a can or box using synthetic resin having a conductive metal (Fe, Cu, Ni or the like) added thereto is covered above circuit elements 2, so that it is possible to shield electromagnetic waves generated from the circuit elements 2.

The shield 10 is manufactured in the shape of a box having an opened bottom by performing press working on a thin plate so as to cover the circuit elements 2. That is, the shield 10 includes a shield cover 11 corresponding to the top surface thereof and a shield wall 12 corresponding to the sidewall thereof.

In this case, several methods are applied so that the shield 10 is fixed on the circuit board 1. For example, there are a method of forming holes in the circuit board 1, protruding support legs at lower ends of the shield wall 12 of the shield 10 so as to correspond to the respective holes, inserting the support legs into the respective holes and then fixing the shield 10 to the circuit board 1, and a method of fixing the shield 10 to the circuit board 1 by previously mounting a fixture or a plurality of clips on the circuit board 1 so as to be coupled to the circumference of the shield wall 12 of the shield 10 and then inserting the shield wall 12 of the shield 10 into the fixture or clips.

However, the most serious problem of the method for shielding electromagnetic waves using the shield 10 is that if the shield 10 is fixed on the circuit board 1 using any fixing method, it is not easy to separate the shield 1 from the circuit board 1, and therefore, it is very inconvenience in terms of maintenance and repair of the circuit board 2 from now on.

That is, in a case where the protruded support legs of the shield 10 are fixed into the respective holes of the circuit board 1 using solder, it is not easy to remove the solder. In a case where the shield 10 is fixedly inserted into the fixture or the plurality of clips, the shield can be separated from the circuit board 1. However, since the thin shield 10 is easily bent and deformed, it cannot be reused. Therefore, the shield 10 should be replaced with another shield.

### SUMMARY OF THE INVENTION

An embodiment of the present invention is directed to a shield for shielding electromagnetic waves, which can easily perform maintenance and repair of circuit elements without separating the shield from a circuit board even after the shield is fixed on the circuit board.

According to an aspect of the present invention, there is provided a shield for shielding electromagnetic waves formed in the shape of a box having an opened bottom so as to cover circuit elements disposed on a circuit board. In the shield, the shield is composed of a shield cover corresponding to a top surface thereof and a shield wall corresponding to a sidewall thereof, and the shield cover comprises a frame and a cut-away part cut away at an inside of the frame. The cut-away part opens/closes the inside of the frame of the shield cover as the other side of the cut-away part is rotated using one side of the cut-away part as a rotational axis.

The shield cover may be provided with connection parts constituting the rotational axis at the other of the cut-away part by being connected to the frame at the one side of the cut-away part so that the entire circumferential line of the cut-away part is not cut away and separated from the frame.

The cut-away part of the shield cover may be provided with a protruding piece formed at the other side thereof, and the protruding piece may be stuck to a bottom surface of the frame of the shield cover so as to limit upward rotation at the other side of the cut-away part.

The cut-away part of the shield cover may be provided with rib pieces protruded from the circumferential line of the cut-away part, and the rib piece may be stuck to a top surface of the frame of the shield cover so as to limit downward rotation at the other side of the cut-away part.

A plurality of support holes may be formed in the circuit board so as to pass through the circuit board along the circumference of the circuit elements, and a plurality of support legs may be formed to protrude from the lower end of the shield wall of the shield so that the support legs are inserted into the respective support holes of the circuit board and then fixed to the circuit board.

A fixture or a plurality of clips may be mounted to the circuit board along the circumference of the circuit elements to be shield, and the lower end of the shield wall of the shield may be fixedly inserted into the fixture or the plurality of clips.

In the shield for shielding electromagnetic waves according to the present invention, the cut-away part of the shield cover is rotated without separating the shield from the circuit board even after the shield is fixed on the circuit board, thereby easily performing maintenance and repair of the circuit elements.

Further, the rotation of the cut-away part with respect to the frame of the shield cover is performed through the connection parts, so that the cut-away part and the connection parts can be simultaneously formed without using a separate rotator in the press working of the thin plate.

Furthermore, excessive upward or downward rotations of the cut-away part are limited through the protruding piece and the rib pieces, so that the cut-away part can be firmly fixed.

### BRIEF DESCRIPTION OF THE DRAWINGS

The above and other aspects, features and other advantages will be more clearly understood from the following detailed description taken in conjunction with the accompanying drawings, in which:

FIG. 1 is a perspective view illustrating a conventional shield for shielding electromagnetic waves;

FIG. 2 is a perspective view illustrating a shield for shielding electromagnetic waves according to an embodiment of the present invention;

FIG. 3 is a main part perspective view of the shield in the embodiment of the FIG. 2;

FIG. 4 is a sectional view taken along line A-A′ in the embodiment of FIG. 2;

FIG. 5 is a perspective view illustrating a shield for shielding electromagnetic waves according to another embodiment of the present invention;

FIG. 6 is a main part perspective view of the shield in the embodiment of the FIG. 5;

FIGS. 7 and 8 are perspective views illustrating a use state of a protruding piece and rib pieces in the embodiment of FIG. 6; and

FIG. 9 is a sectional view taken along line B-B′ in the embodiment of FIG. 5.

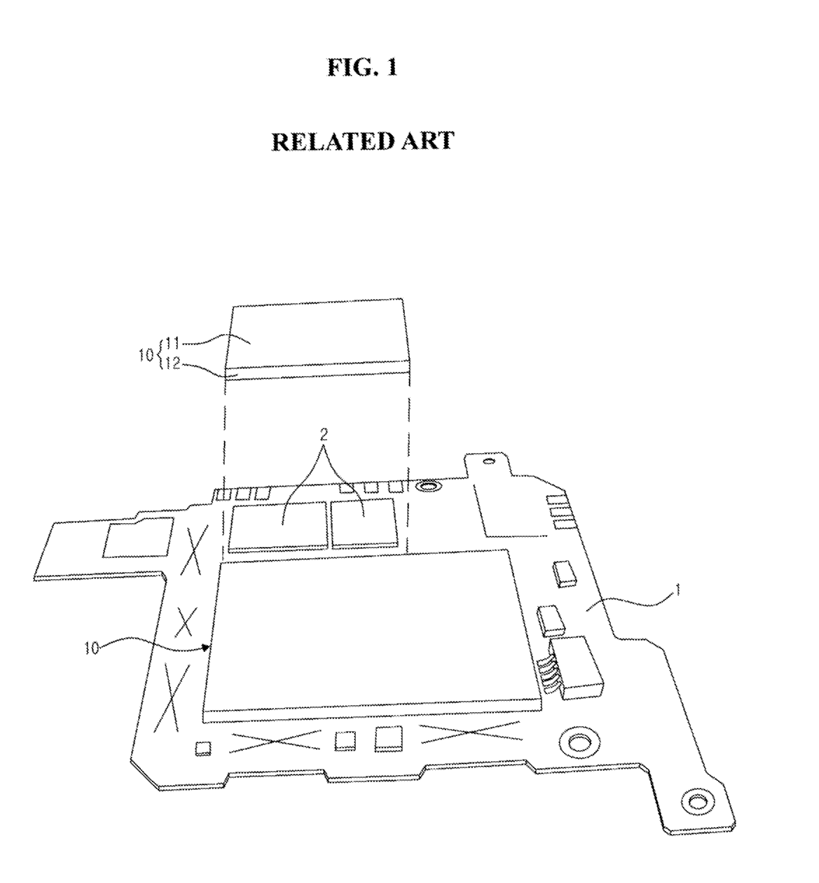

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

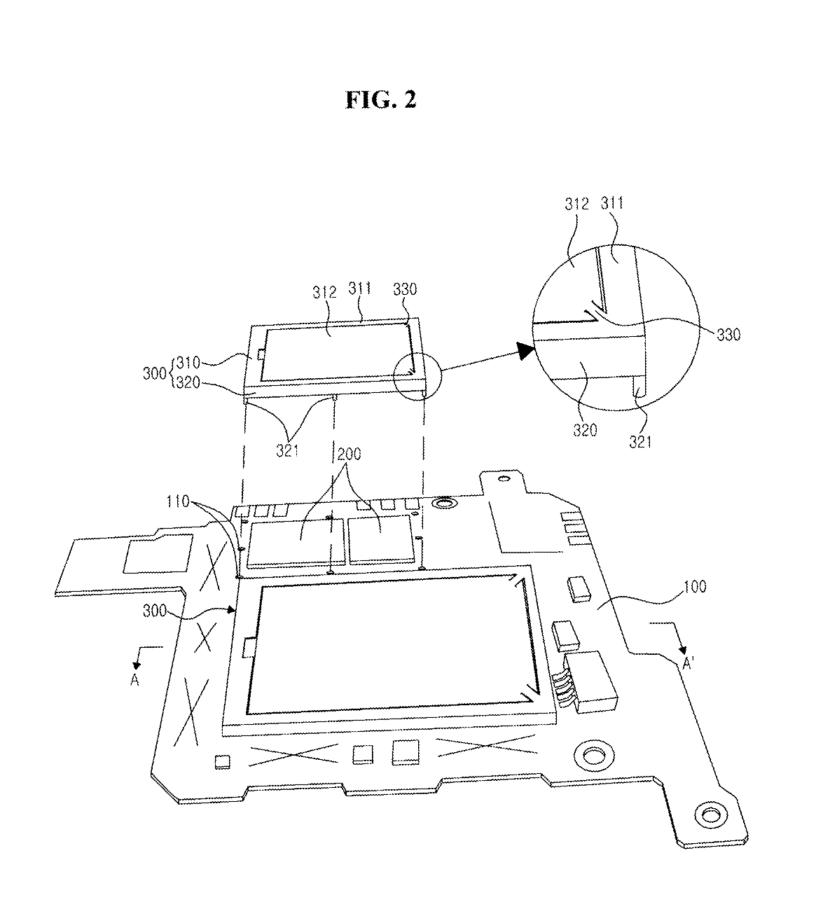

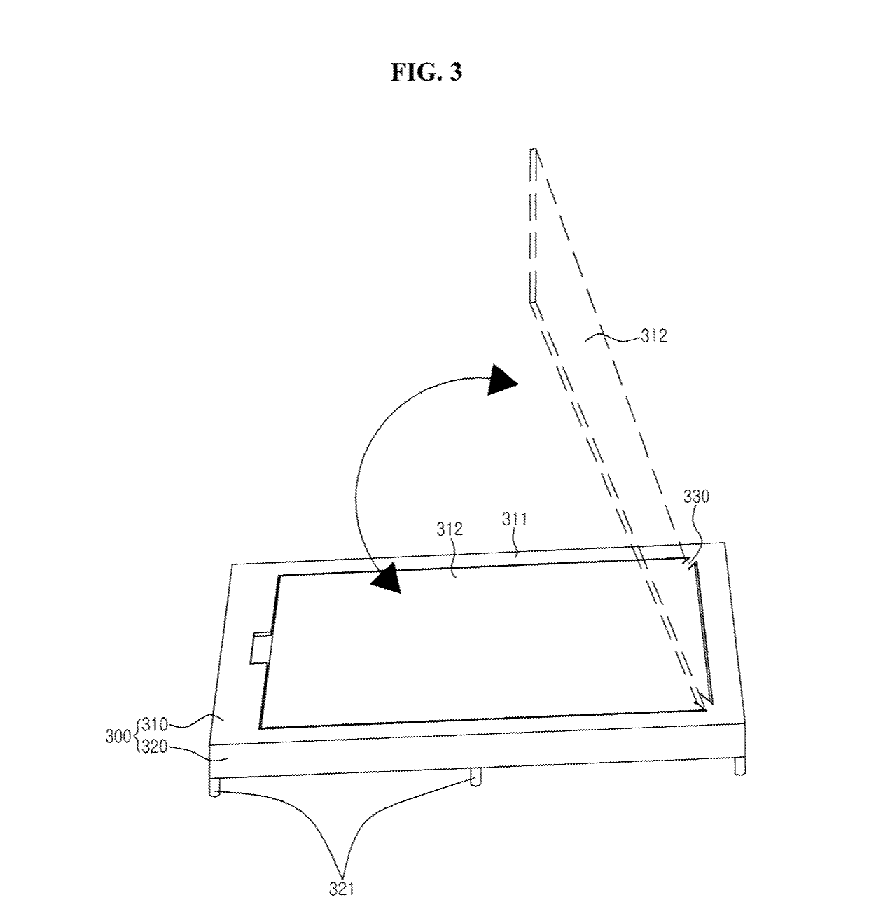

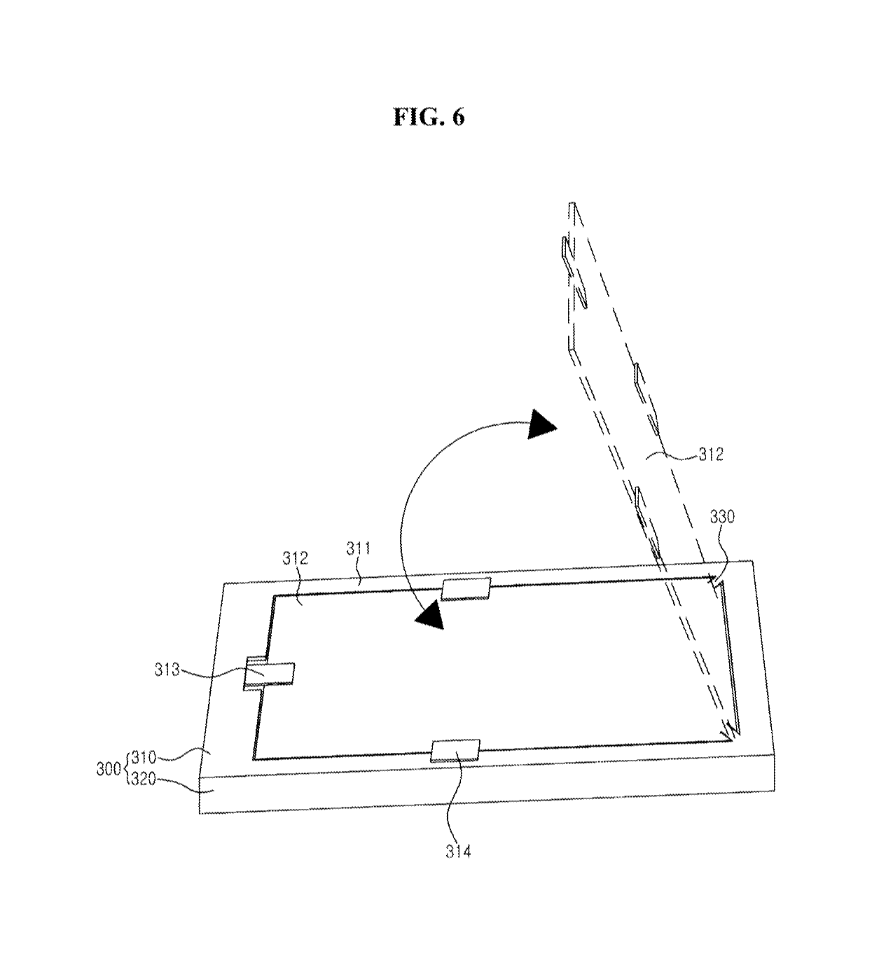

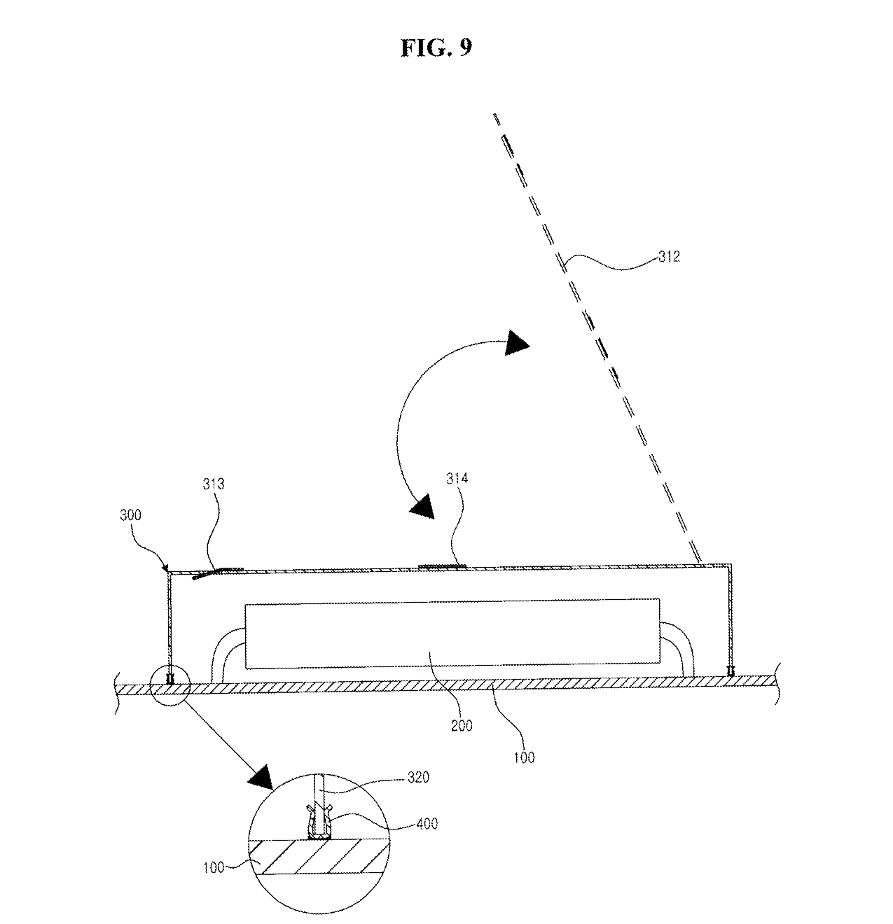

A shield for shielding electromagnetic waves according to the present invention, as illustrated in FIGS. 2 to 9, is manufactured in the shape of a box having an opened bottom so as to cover circuit elements 200 disposed on a circuit board 100. More specifically, the shield 300 is composed of a shield cover 310 and a shield wall 320. The shield cover 310 may include a frame 311, a cut-away part 312 and connection parts 330. The cut-away part 312 may include a protruding piece 313 and rib pieces 314.

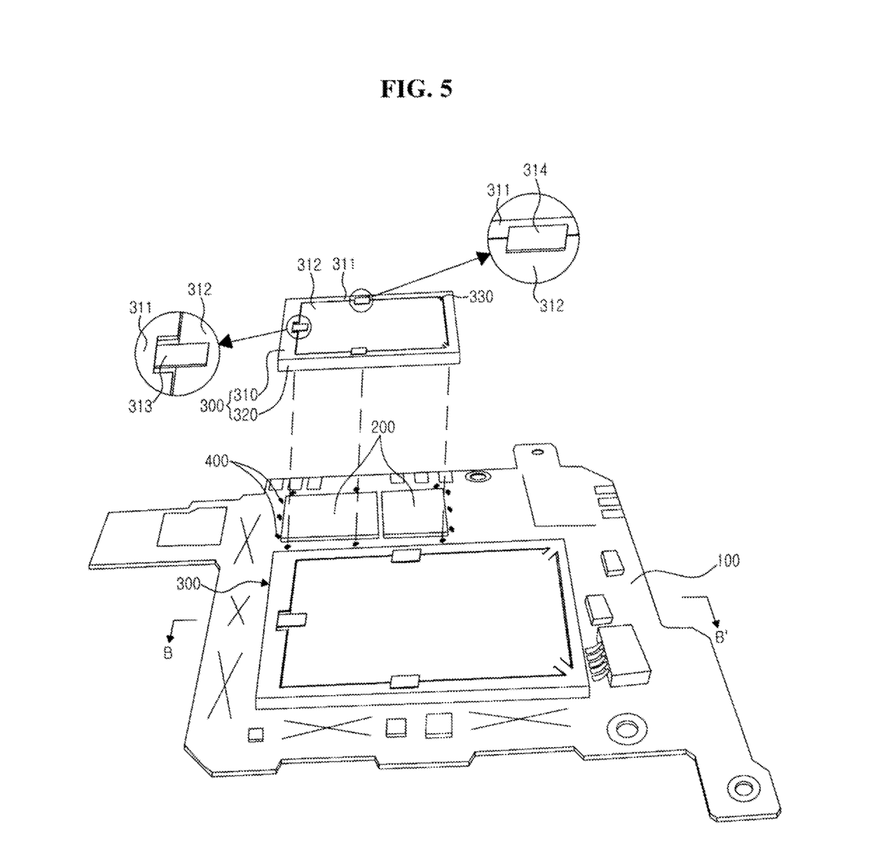

The circuit board 100 is a flat plate made of an insulating material. As illustrated in FIGS. 2 and 5, electronic components, i.e., the circuit elements 200 and the like, are attached to the circuit board 100, and a circuit is formed on the circuit board 100 by connecting the circuit elements 200 to one another. In addition to the circuit elements 200 to be shielded, connection ports or all elements constituting other electric circuits may be disposed on the circuit board 100.

The shield 300 according to the present invention is used to shield electromagnetic waves generated from the circuit elements 200 by covering the circuit elements 200 disposed on the circuit board 100 as described above. The shield is manufactured in the shape of a box having an opened bottom as illustrated in FIGS. 2 to 9. That is, the shield 300 is composed of the shield cover 310 corresponding to the top surface thereof and the shield wall 320 corresponding to the sidewall thereof so as to have the shape of a box of which inside is hollowed and bottom is opened. Thus, the shield 300 can cover the circuit elements 200 disposed on the circuit board 100 from the upper part of the circuit elements 200.

In this case, the shield cover 310, as illustrated in FIGS. 2 to 9, includes the frame 311 and the cut-away part 312 cut away at the inside of the frame 311, and the cut-away part 312 opens/closes the inside of the frame 311 of the shield cover 310 as the other side of the cut-away part 312 is rotated using one side of the cut-away part 312 as a rotational axis. A separate rotating coupler such as a hinge may be provided to use the one side of the cut-away part 312 of the shield cover 310. However, since the number of assembling processes is increased according to the number of separate components, the rotational axis is preferably formed at the one side of the cut-away part 312 at the same time in manufacturing of the shield 300.

That is, since the shield 300 is usually manufactured by performing press working on a flat thin plate, the press working is performed on the thin plate that is a raw material of the shield 300 so that the shield cover 310 is cut away into the frame 311 and the cut-away part 312 while forming the shield cover 310 and the shield wall 320. As illustrated in FIGS. 2 to 4, the connection parts 330 connected to the frame 311 at the one side of the cut-away part 312 are provided so that the entire circumferential line of the cut-away part 312 is not cut away and separated from the frame 311 in processing of the shield cover 310. Here, the connection parts 330 constitute the rotational axis at the other side of the cut-away part 312. The cut-away part 312 is rotated using the connection parts 330 as the rotational axis, and the inside of the frame 311 of the shield cover 310 can be opened or closed according to the rotation of the cut-away part 312.

Meanwhile, if the cut-away 312 is rotated using the connection parts 330 as the rotational axis, the connection parts 330 may be plastically deformed by excessive downward or upward rotations or frequent rotations of the cut-away part 312 with respect to the frame 311. Therefore, as the cut-away part 312 is not fixed on the same plane as the frame 311 and comes off higher than or falls down lower than the height of the frame 311, the circuit elements 200 in the inside of the shield 300 may be interfered by the cut-away part 312. In order to solve such a problem, the shield 300 may further include the protruding piece 313 and the rib pieces 314 as illustrated in FIGS. 5 to 9.

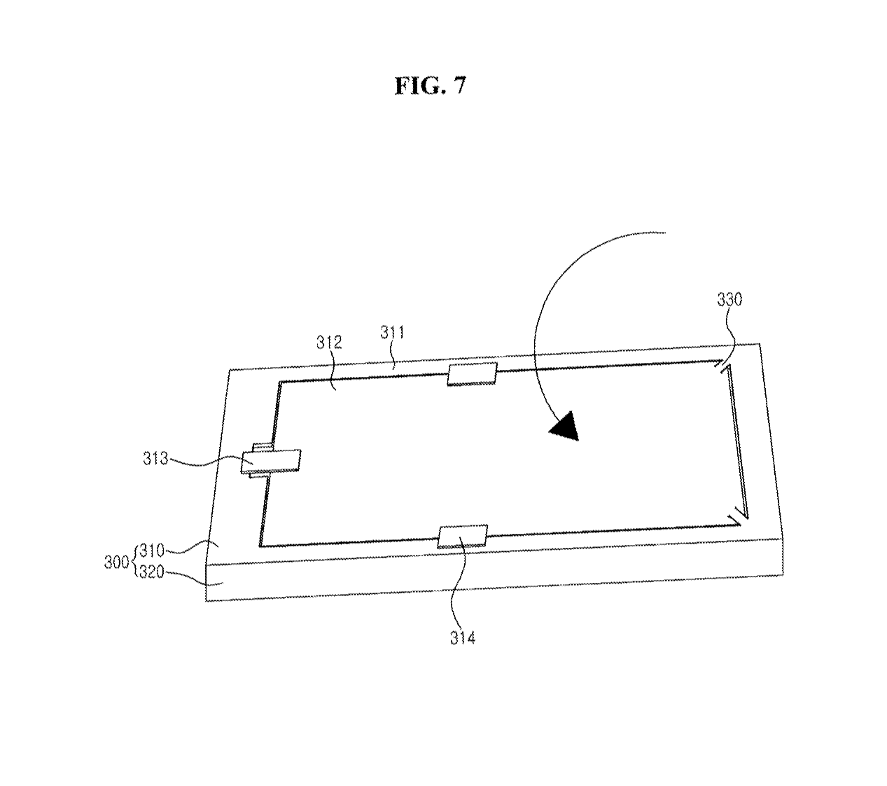

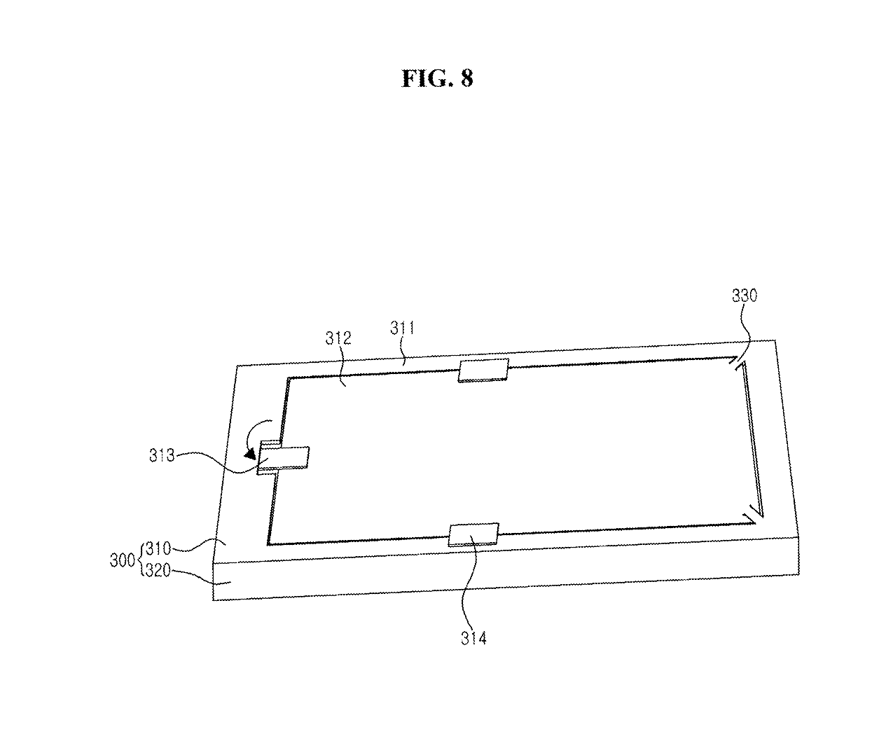

That is, the cut-away part 312 of the shield cover 310 is provided with the protruding piece 313 formed at the other side thereof, and the protruding piece 313 is stuck to a bottom surface of the frame 311 of the shield cover 310 so as to limit the upward rotation at the other side of the cut-away part 312. The protruding piece 313 is made of a flexible or elastic material such as rubber or synthetic resin, and formed to protrude at the other side of the cut-away part 312. Thus, in a case where the cut-away part 312 comes off higher than the height of the frame 311 when performing upward rotation of the cut-away part 312 and then performing downward rotation of the cut-away part 312 so as to close the inside of the frame 311, the protruding piece 313 is stuck to the bottom surface of the frame 311 by being pressed down to the bottom surface of the frame 311 as illustrated in FIGS. 7 and 8. Accordingly, the upward rotation at the other side of the cut-away 312 is limited, thereby fixing the cut-away part 312.

The cut-away part 312 of the shield cover 310 is provided with the rib pieces 314 protruded from the circumferential line of the cut-away part 312, and the rib piece 314 is stuck to a top surface of the frame 311 of the shield cover 310 so as to limit the downward rotation at the other side of the cut-away part 312. Like the protruding piece 313, the rib pieces 314 may be made of rubber or synthetic resin, but is not necessarily flexible or elastic. That is, as illustrated in FIGS. 7 and 8, the rib piece 314 is stuck to the top surface of the frame 311 so that the cut-away part 312 does not fall down lower than the height of the frame 311 when performing upward rotation of the cut-away part 312 and then performing downward rotation of the cut-away part 312 so as to close the inside of the frame 311. Accordingly, the downward rotation at the other side of the cut-away part 312 is limited.

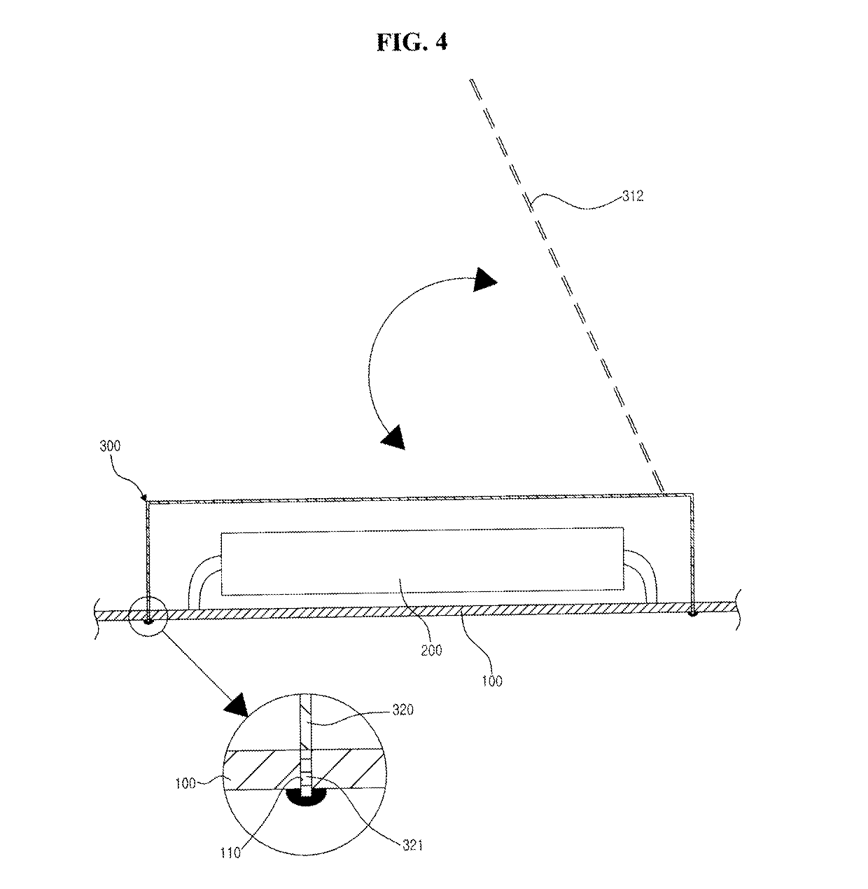

In the shield according to the present invention configured as described above, it is sufficient that the circuit elements 200 in the inside of the shield 300 can be shield, and it is not important how to fix the shield 300 to the circuit board 100. However, as illustrated in FIGS. 2 to 4, a plurality of support holes 110 are formed in the circuit board 100 so as to pass through the circuit board 100 along the circumference of the circuit elements 200, and a plurality of support legs 321 are formed to protrude from the lower end of the shield wall 320 of the shield 300. Thus, the support legs 321 can be inserted into the respective support holes 110 of the circuit board 100 and then fixed to the circuit board 100. In this case, the support legs 321 are fixed to the circuit board 100 at bottoms of the respective support holes 110 of the circuit board 100 through welding as illustrated in FIG. 4.

As illustrated in FIGS. 5 to 9, a fixture (not shown) or a plurality of clips 400 may be mounted to the circuit board 100 along the circumference of the circuit elements 200 to be shield, and the lower end of the shield wall 320 of the shield 300 may be fixedly inserted into the fixture or the plurality of clips 400. It is sufficient that the fixture distinguished from the clip 400 has a configuration except the clips 400, into which the shield wall 320 can be fixedly inserted, and it is not important that the fixture has any shape or connection relation.

As described above, in the shield according to the present invention, the cut-away part 312 of the shield cover 310 is rotated without separating the shield 300 from the circuit board 100 even after the shield 300 is fixed on the circuit board 100, thereby easily performing maintenance and repair of the circuit elements 200.

Further, the rotation of the cut-away part 312 with respect to the frame 311 of the shield cover 310 Is performed through the connection parts 330, so that the cut-away part 312 and the connection parts 330 can be simultaneously formed without using a separate rotator in the press working of the thin plate.

Furthermore, excessive upward or downward rotations of the cut-away part 312 are limited through the protruding piece 313 and the rib pieces 314, so that the cut-away part 312 can be firmly fixed.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A shield for shielding electromagnetic waves formed in the shape of a box having an opened bottom so as to cover circuit elements disposed on a circuit board, wherein:
the shield is composed of a shield cover corresponding to a top surface thereof and a shield wall corresponding to a sidewall thereof;
the shield cover comprises a frame and a cut-away part cut away at an inside of the frame; and
the cut-away part opens/closes the inside of the frame of the shield cover as the other side of the cut-away part is rotated using one side of the cut-away part as a rotational axis, and is provided with a protruding piece formed at the other side thereof so that the protruding piece limits upward rotation at the other side of the cut-away part by being stuck to a bottom surface of the frame of the shield cover.

2. The shield of claim 1, wherein the shield cover is provided with connection parts constituting the rotational axis at the other of the cut-away part by being connected to the frame at the one side of the cut-away part so that the entire circumferential line of the cut-away part is not cut away and separated from the frame.

3. The shield of claim 1, wherein the cut-away part of the shield cover is provided with rib pieces protruded from the circumferential line of the cut-away part, and the rib piece is stuck to a top surface of the frame of the shield cover so as to limit downward rotation at the other side of the cut-away part.

4. The shield of claim 1, wherein a plurality of support holes are formed in the circuit board so as to pass through the circuit board along the circumference of the circuit elements, and a plurality of support legs are formed to protrude from the lower end of the shield wall of the shield so that the support legs are inserted into the respective support holes of the circuit board and then fixed to the circuit board.

5. The shield of claim 1, wherein a fixture or a plurality of clips are mounted to the circuit board along the circumference of the circuit elements to be shield, and the lower end of the shield wall of the shield is fixedly inserted into the fixture or the plurality of clips.
